(19) United States
(12) Patent Application Publication
(10) Pub. No.: US 2009/0325477 A1
(43) Pub. Date: Dec. 31, 2009

(54) Cooling of Rack Mounted Equipment

(76) Inventor: Thomas Hanlon, Murietta, CA (US)

Correspondence Address: Thomas Hanlon, 3658 Fairway Drive, La Mesa, CA, 91941, US

(21) Appl. No.: 11/426,353

(22) Filed: Jun. 30, 2008

(51) Int. Cl. H05K 5/00

(52) U.S. Cl. 454/184; 454/238

(57) ABSTRACT

A rack and method of cooling wherein cold, sub ambient air is introduced into an electronic enclosure from below. In some embodiments a plurality of parallel arrange air movers pushes cold air to a series of ducts. Axial flow fans, or other types of fans, are secured to where cold air enters the ducting. Cold air is ducted to cabinets through at least one large plenums. The size of the duct allows for large amounts of cold air to move at low velocity and to travel through two parallel ducts into a large plenum. An even distribution of cold air is directed towards the exhaust through a screen. One side of the plenum is open to the equipment to be cooled. A screen evens out the pressure distribution of cold air along the length of the plenum prior to exhaust.

### FIELD OF THE INVENTION

This invention generally relates to a method to cool rack mounted equipment and particularly the invention relates to uniform delivery of large volumetric flows to cool a tall rack of equipment.

### BACKGROUND OF THE INVENTION

Electronic equipment is commonly arranged on racks. These racks meet industry standards for a form and fit. To cool the equipment that goes into racks, electronic equipment is usually designed to draw air from the same side, the “front”. Further, electronic equipment may be located in a special room where the equipment is on a raised floor. The “subfloor” that exists underneath has ample room for power, data and communications cables, and has cold air running laterally throughout the subfloor. In some applications, cold subfloor air is introduced in proximity to the “front” of the racks to further cool equipment. As electronic equipment becomes more powerful, it is necessary to introduce larger amounts of cold air from the subfloor to cool equipment. For racks designed to industry standards, for example EIA-310, IEC 60297 and Din 41494 SC48D, there is limited space within the rack to accommodate these larger flows. Theoretically, this is overcome using high velocity air, but the air moves so fast through small ducts that it cannot be delivered evenly to the equipment. A method was needed to move large quantities of cold subfloor air to the inlet surface of electronic equipment within the rack AND distribute that air evenly to the entire rack. This design is intended to fulfill the need to evenly introduce of large amounts of sub-ambient air to the surfaces of rack equipment.

### SUMMARY OF THE INVENTION

In accordance with first aspect of the invention, cold, sub ambient air is introduced into an electronic enclosure from below. In some embodiments a plurality of parallel arrange air movers pushes cold air to a series of ducts, or series of ducts. In illustrative embodiment axial flow fans, or other types of fans, are secured to where cold air enters the ducting.

In accordance with the second aspect of the invention cold air is ducted to cabinets through at least one large plenums. In some embodiments, the size of the duct allows for large amounts of cold air to move at low velocity. In illustrative embodiment, cold air travels through two parallel ducts into a large plenum.

In accordance with the third aspect of the invention an even distribution of cold air is directed towards the exhaust through a screen. In some embodiments one side of the plenum is open to the equipment to be cooled. In illustrative embodiment, a screen evens out the pressure distribution of cold air along the length of the plenum prior to exhaust.

In accordance with the fourth aspect of the invention cold air is introduced to the “front” of the heat load” through a long narrow vent. In some embodiments exhaust cold air is directed towards the heat load and mixed with ambient air. In illustrative embodiment in this illustration the cold air is turned 90 degrees to deliver large volumetric flows along a narrow exhaust vent.

In accordance with the fifth aspect of the invention cold air enters the rack equipment. In some embodiments the cold air is directed to the “front” of the rack equipment. In illustrative embodiment, cold air is ducted to the equipment. In other embodiments fans resident in the equipment draw the ducted cold air from the “front” of the rack. In other embodiments cold air can be mixed with ambient air.

### BRIEF DESCRIPTION OF THE DRAWINGS

The foregoing sections and the advantages of the invention will be appreciated more fully from the following further description thereof with reference to accompanying drawings wherein;

FIG. 1 shows a perspective view of an example of a rack with electronic equipment installed.

FIG. 2 shows a perspective view of a rack with cold air moved by fans moved up to side plenums in accordance with illustrative embodiments of the invention.

FIG. 3 shows a perspective view of how cold air is then redirected through a screen to even the pressure and flow along the entire long height of the rack in accordance with illustrative embodiments of the invention.

FIG. 4 shows a perspective view of how cold air is then redirected to the equipment within the rack in accordance with illustrative embodiments of the invention.

FIG. 5 shows a perspective view of the inventions in accordance with illustrative embodiments of the inventions including the fan tray and plenums assembled to a rack.

FIG. 6 shows a cross section detail view of how cold air is directed through a plenum towards the “front mount” of the rack.

FIG. 7 shows an exploded view of the invention in according with illustrative embodiments of the invention including fan tray, fans, plenums with plenum covers, and, screens.

### DESCRIPTION OF ILLUSTRATIVE EMBODIMENTS

In illustrative embodiments of the invention, large heat loads require large volumetric flows of cold subfloor air. There is limited space to deliver large volumes of cold subfloor air however, so that either insufficient air is distributed equally, or sufficient air is delivered unequally because the air is moving too fast. We have overcome these problems this by an arrangement of at airmovers, at least one plenum within the rack, a settling screen that evens the flow along the screens, and then directing the air through long narrow ducts towards the equipment. Details of illustrative embodiments are discussed below.

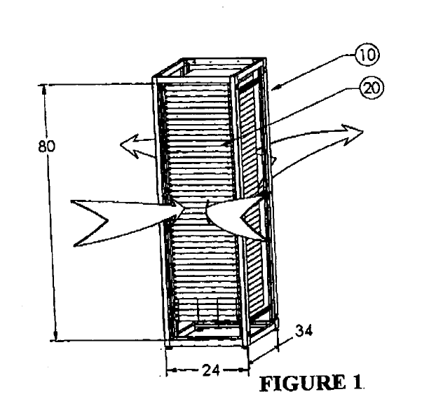

FIG. 1 shows a perspective view of a reference view of an what a rack (10) for electronic equipment (20) would commonly look like. Large arrows denote the industrial practice of having ambient air enter the “front mounts” of the rack equipme and exhaust 180 degrees opposing. This figure is used to clarify a common industry practice of (1) mounting electronic equipment into tall racks and (2) cooling rack equipment fans by fans that are internal to that equipment. This figure and its dimensions in inches are for reference only and not part of the invention.

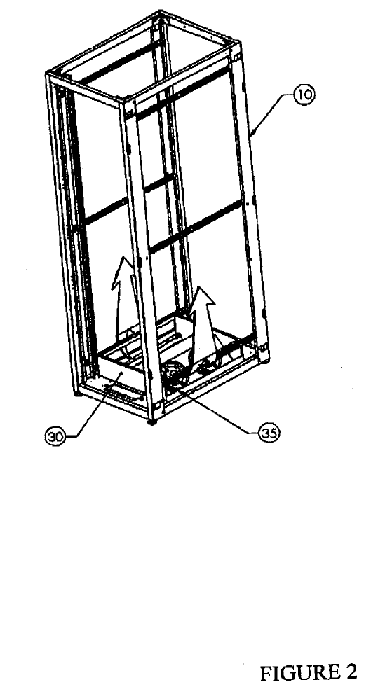

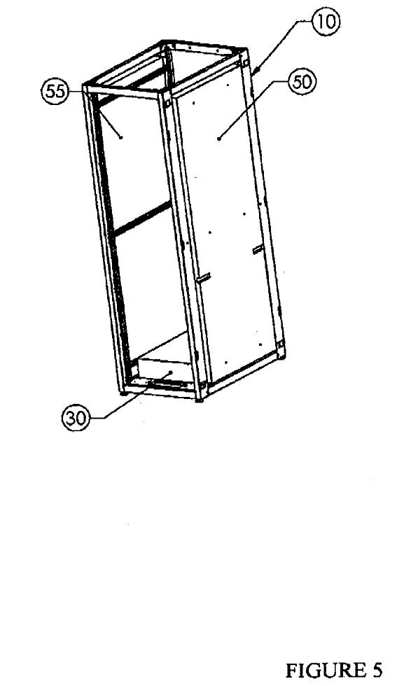

FIG. 2 shows a perspective view of an empty rack (10). Located at the base of the rack is a fan tray (30). Fans or equivalent air-moving devices (35) pull cold air from the subfloor. As the large arrows indicate, the cold air is pushed by fans up into ducts on either side of the of the rack (not shown) in accordance with illustrative embodiments of the invention. The ducts are shown in FIG. 5. These large side ducts allow the air to slow down for even distribution to the front of the cabinet.

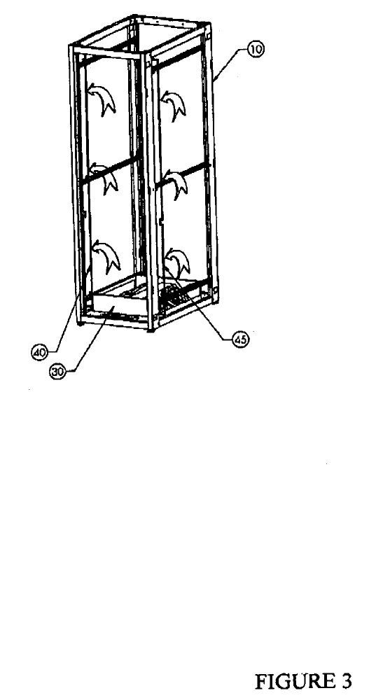

FIG. 3 shows a perspective view of how cold air is directed through a screen to even the pressure and flow along the length of the rack in accordance with illustrative embodiments of the invention. Cold air within the side ducts is moving rapidly, with pressure uneven throughout the length of the plenum. To even the pressure, the cold air from the fan tray (30) is then turned 90 degrees to face a settling screen (40 or 45). The cold air pressure and volumetric airflow will be more even as it passes through the screen.

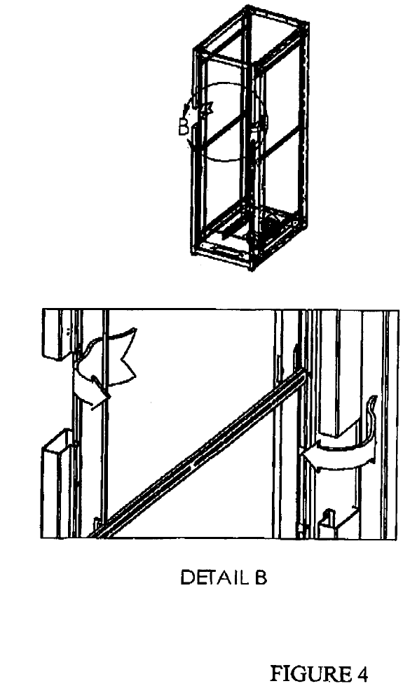

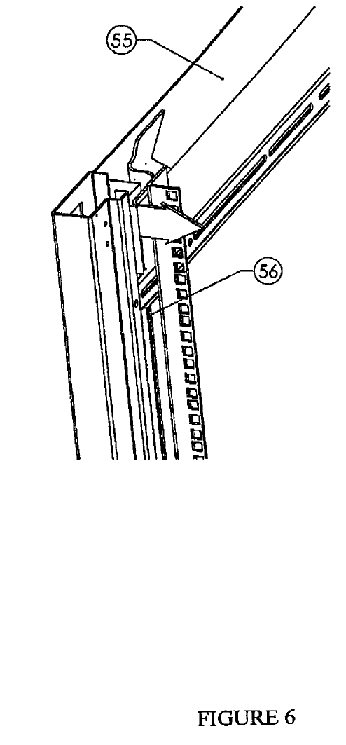

FIG. 4 shows a perspective view of how cold air is directed to the equipment within the rack in accordance with illustrative embodiments of the invention. Downstream from the settling screens, cold air must be redirected to the inlet side of the electronic equipment as demonstrated by the large arrows. Small vents on the side of the plenums (see FIG. 6) redirect cold air to the equipment inlet side. In Detail B of FIG. 4, parts of the rails have been cleared away to clarify the redirection of cold air.

FIG. 5 shows a perspective view of the inventions in accordance with illustrative embodiments of the inventions including the fan tray (30) plenums (50 and 55) assembled to a rack (10).

FIG. 6 shows a cross section detail view of how cold air is directed through a plenum (55) towards the “front mount” of the rack”. The direction of air is indicated by the large arrow exhausting out the side vent (56)

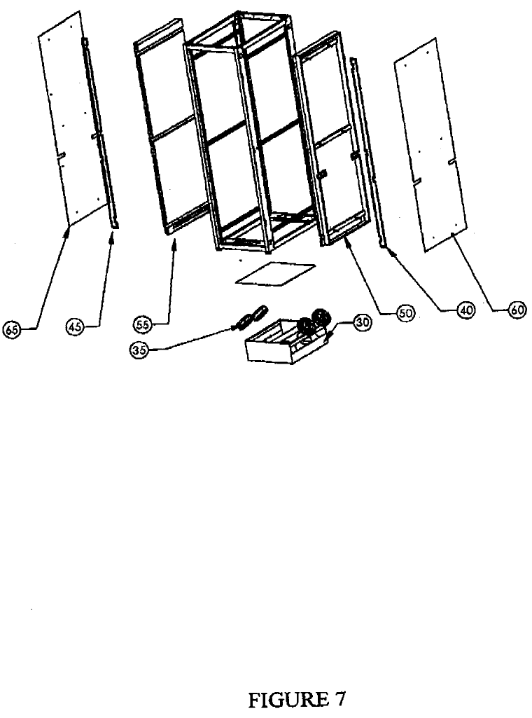

FIG. 7 shows an exploded view of the invention in according with illustrative embodiments of the invention including fan tray (30), fans (35), plenums (50 and 55) with plenum covers (60 and 65), screens (40 and 45).

I claim:

1. A method for converting nonisobaric turbulent flow to uniformly distributed airflow to rack mounted electronic equipment comprising of: an enclosure, air moving device, plenum for collecting air, settling screen and exhaust vent.

2. The settling screen recited in claim one wherein the material is a polymer or a metal with a plurality of openings to allow air to pass axially through.

3. The air-moving device in claim one wherein the air mover shall be a fan, blower, or motorized impeller.

4. The air-moving device in claim one wherein there are multiple air movers in series or in parallel.

5. The plenum recited in claim one wherein there is more than one plenum.

6. The exhaust vent in claim one wherein there is more than one exhaust vent.

7. The settling screen recited in claim 1 wherein the open area is 10% to 90%.
